(19) United States
(12) Patent Application Publication
(10) Pub. No.: US 2025/0040150 A1
(43) Pub. Date: Jan. 30, 2025

(54) CROSS-POINT OVONIC FRUSTUM MEMORY DEVICE AND METHOD OF MAKING THE SAME

(71) Applicant: WESTERN DIGITAL TECHNOLOGIES, INC., SAN JOSE, CA (US)

(72) Inventors: Lei WAN, San Jose, CA (US); Michael Nicolas Albert TRAN, San Jose, CA (US)

(21) Appl. No.: 18/358,768

(22) Filed: Jul. 25, 2023

(51) Int. Cl. H10B 63/00; G11C 13/00; H10N 70/00

(52) U.S. Cl. CPC H10B 63/24; G11C 13/004; G11C 13/0069; H10B 63/80; H10N 70/063; H10N 70/066; H10N 70/821; H10N 70/841; H10N 70/882

(57) ABSTRACT

An ovonic memory element includes a first electrode, a second electrode, and an ovonic threshold switching material portion located between the first electrode and the second electrode. A first surface of the ovonic threshold switching material portion facing the first electrode is wider than an opposing second surface of the ovonic threshold switching material portion facing the second electrode.

### FIELD

The present disclosure relates generally to the field of ovonic memory devices, and particularly to a cross-point ovonic frustum memory device and methods of manufacturing the same.

### BACKGROUND

A random access memory device is a memory device containing memory cells that allow random access, e.g., access to any selected memory cell upon a command for reading the contents of the selected memory cell. The memory cells of the random access memory device may be arranged in a cross-point configuration, where a bit memory cell resides at every intersection of a bit line and a word line.

### SUMMARY

According to an aspect of the present disclosure, an ovonic memory element includes a first electrode, a second electrode, and an ovonic threshold switching material portion located between the first electrode and the second electrode. A first surface of the ovonic threshold switching material portion facing the first electrode is wider than an opposing second surface of the ovonic threshold switching material portion facing the second electrode.

According to yet another aspect of the present disclosure, a method of forming a memory device is provided. The method comprises: forming first electrically conductive lines laterally extending along a first horizontal direction; forming an ovonic threshold switching material layer over the first electrically conductive lines; patterning the ovonic threshold switching material layer into a two-dimensional array of ovonic threshold switching material portions having a respective shape of a frustum; and forming second electrically conductive lines laterally extending along a second horizontal direction over the two-dimensional array of ovonic threshold switching material portions.

### BRIEF DESCRIPTION OF THE DRAWINGS

FIG. 1 is a schematic diagram of a memory device including ovonic memory cells of the present disclosure in an array configuration.

FIG. 2A illustrates a perspective view of a first exemplary multi-tier ovonic memory array and a magnified view of an ovonic memory cell.

FIG. 2B illustrates a perspective view of a second exemplary multi-tier ovonic memory array and a magnified view of an ovonic memory cell.

FIGS. 3A-3F are sequential perspective views of a first exemplary structure during formation of a two-dimensional array of ovonic memory cells according to a first embodiment of the present disclosure.

FIGS. 4A-4D are sequential perspective views of a second exemplary structure during formation of a two-dimensional array of ovonic memory cells according to a second embodiment of the present disclosure.

FIGS. 5A-5G are sequential perspective views of a third exemplary structure during formation of a two-dimensional array of ovonic memory cells according to a third embodiment of the present disclosure.

FIG. 6 schematically illustrates variations in ΔVth/Vth for various shapes of ovonic threshold switching material portions.

### DETAILED DESCRIPTION

As discussed above, the embodiments of the present disclosure are directed to a cross-point ovonic memory device and methods of manufacturing the same, the various aspects of which are discussed herein in detail. In self-selecting cross-point memory devices based on ovonic threshold switches, the threshold voltage of an ovonic material has a small hysteresis effect, and can increase if a previously applied electrical pulse (e.g., programming pulse) had an opposite polarity relative to a subsequently applied electrical pulse (e.g., read pulse). In other words, the absolute value of the threshold voltage of the device during a read voltage pulse increases if the previous programming voltage pulse had an opposite polarity from the read voltage pulse. This phenomenon is utilized in a memory device employing the ovonic threshold switch (OTS) material itself as a memory material, i.e., an OTS-only memory, rather than using the OTS material as a selector element for another type of memory material, such as a magnetic memory material. Such an OTS-only memory device may provide device scalability and possible additional advantages. However, the OTS-only memory device has a narrow memory window, i.e., a small difference in the threshold voltages between a forward programming condition (in which a previously applied programming pulse has the same polarity as the sensing pulse) and a reverse programming condition (in which a previously applied programming pulse has an opposite polarity relative to the sensing pulse). A useful metric for determining operability of the OTS-only memory is A Vth/Vth which is the ratio of the difference between the threshold voltages under the reverse programming condition and the threshold voltages under the forward programming condition, to the threshold voltage under the forward programming condition. In one embodiment, A Vth may be the difference between Vth+/− and Vth+/+, where Vth+/− is the threshold voltage going from a positive voltage pulse to a negative voltage pulse, and Vth+/+ is the threshold voltage going from a positive voltage pulse to another positive voltage pulse. In this case, ΔVth/Vth={(Vth+/−)−(Vth+/+)}/(Vth+/+). Prior art OTS-only devices exhibit values of ΔVth/Vth of about 12% or less. The embodiments of the present disclosure provide an OTS-only device with an improved value of A Vth/Vth.

The drawings are not drawn to scale. Multiple instances of an element may be duplicated where a single instance of the element is illustrated, unless absence of duplication of elements is expressly described or clearly indicated otherwise. Same reference numerals refer to the same element or to a similar element. Elements having the same reference numerals are presumed to have the same material composition unless expressly stated otherwise. Ordinals such as “first,” “second,” and “third” are employed merely to identify similar elements, and different ordinals may be employed across the specification and the claims of the instant disclosure. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, an “in-process” structure or a “transient” structure refers to a structure that is subsequently modified.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layer thereupon, thereabove, and/or therebelow.

As used herein, a “layer stack” refers to a stack of layers. As used herein, a “line” or a “line structure” refers to a layer that has a predominant direction of extension, i.e., having a direction along which the layer extends the most.

As used herein, a “conductive material” refers to a material having electrical conductivity greater than 1.0×10⁵ S/cm. As used herein, an “insulating material” or a “dielectric material” refers to a material having electrical conductivity less than 1.0×10⁻⁶ S/cm. As used herein, a “metallic material” refers to an electrically conductive material including at least one metal element therein. All measurements for electrical conductivities are made at the standard condition.

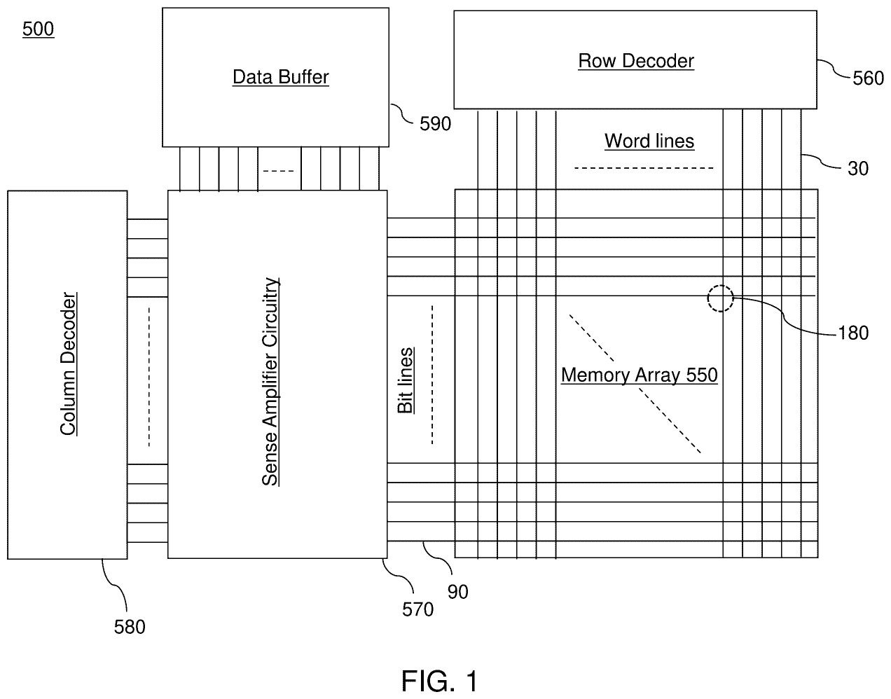

Referring to FIG. 1, a schematic diagram is shown for an ovonic memory device including an array of ovonic memory cells 180 of an embodiment of the present disclosure in an array configuration. The ovonic memory device can be configured as a random access memory (RAM) device 500.

The RAM device 500 of an embodiment of the present disclosure includes a memory array region 550 containing an array of the respective ovonic memory cells 180 located at the intersection of the respective word lines (which may comprise first electrically conductive lines 30 as illustrated or as second electrically conductive lines 90 in an alternate configuration) and bit lines (which may comprise second electrically conductive lines 90 as illustrated or as first electrically conductive lines 30 in an alternate configuration). The RAM device 500 may also contain a row decoder 560 connected to the word lines, a sense circuitry 570 (e.g., a sense amplifier and other bit line control circuitry) connected to the bit lines, a column decoder 580 connected to the bit lines, and a data buffer 590 connected to the sense circuitry. Multiple instances of the ovonic memory cells 180 are provided in an array configuration that forms the RAM device 500. As such, each of the ovonic memory cells 180 can be a two-terminal device including a respective first electrode and a respective second electrode. It should be noted that the location and interconnection of elements are schematic and the elements may be arranged in a different configuration. Further, an ovonic memory cell 180 may be manufactured as a discrete device, i.e., a single isolated device. Configurations of the ovonic memory cells 180 are described in more detail below.

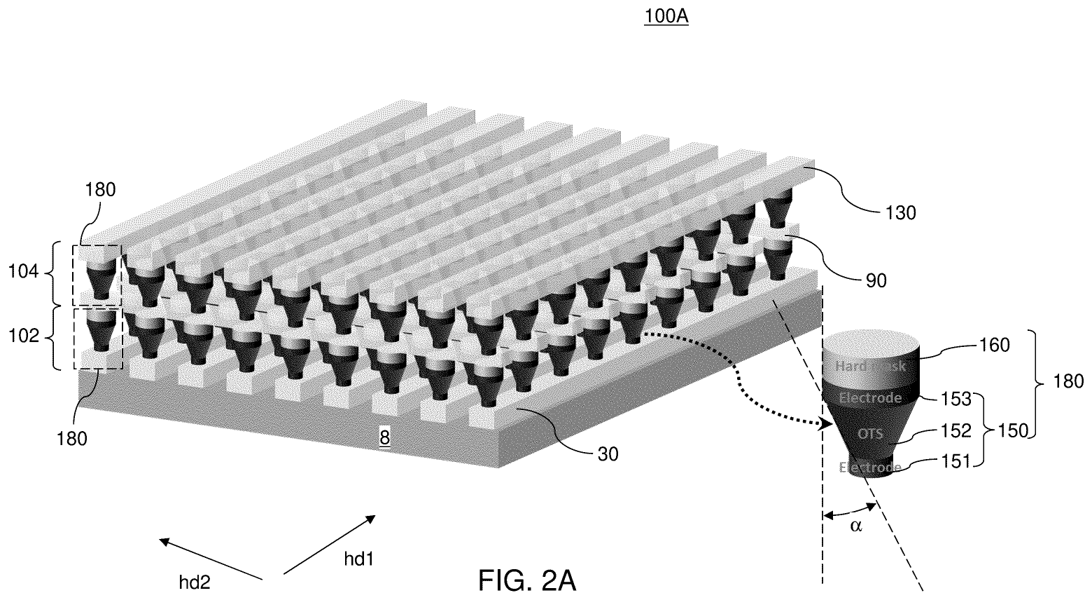

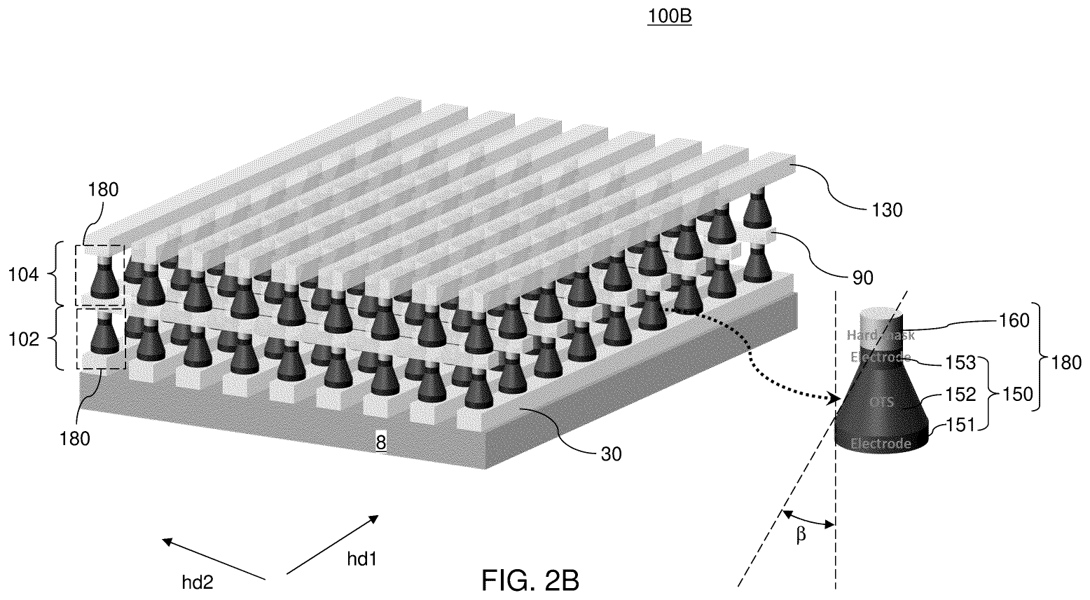

Referring to FIGS. 2A and 2B, a first exemplary multi-tier ovonic memory array 100A and a second exemplary multi-tier ovonic memory array 100B are illustrated, respectively, according to first and second embodiments of the present disclosure, respectively. Each multi-tier memory array may comprise first electrically conductive lines 30 laterally extending along a first horizontal direction hd1 over a substrate 8, second electrically conductive lines 90 laterally extending along a second horizontal direction hd2 which may be perpendicular to the first horizontal direction hd1, and third electrically conductive lines 130 laterally extending along the first horizontal direction hd1. An ovonic memory cell 180 can be located at each cross-point of a respective one of the first electrically conductive lines 30 and a respective one of the second electrically conductive lines 90 to provide the first-tier ovonic memory array 102. An ovonic memory cell 180 can be located at each cross-point a respective one of the second electrically conductive lines 90 and a respective one of the third electrically conductive lines 130 to provide a second-tier ovonic memory array 104 that overlies the first-tier ovonic memory array 102.

Each ovonic memory cell 180 comprises a vertical stack of an ovonic memory element 150 and an optional metallic pillar structure 160. The ovonic memory element 150 may comprise a vertical stack including a first electrode 151, a second electrode 153, and an ovonic threshold switching material portion 152 located between the first electrode 151 and the second electrode 153. The surface of the ovonic threshold switching material portion 152 facing one of the electrodes (151, 153) is wider than the opposing surface of the ovonic threshold switching material portion 152 facing the other one of the electrodes (153, 151). In other words, if the vertical stack includes, from bottom to top relative to the substrate 8, the first electrode 151, the ovonic threshold switching material portion 152, and the second electrode 153, then the wider surface of the ovonic threshold switching material portion 152 may be the top surface facing the overlying second electrode 153 or the bottom surface facing the underlying first electrode 151.

In one embodiment, the ovonic threshold switching material portion 152 has a shape of a frustum. A frustum is a three-dimensional geometrical shape that is derived from a cone or pyramidal shape having any planar base shape in which the tip portion of the cone or pyramidal shape is cut off by a plane parallel to the plane of the base. As such, a frustum may have a circular, elliptical, or polygonal horizontal cross-sectional shape. The wider base may be located above or below the narrower part of the frustrum located in the cut off plane, relative to the substrate 8 supporting the memory element 150.

Each frustum shape of the ovonic memory cell 180 may have a variable horizontal cross-sectional shape that increases in area with a vertical distance from the substrate 8 as illustrated in FIG. 2A, or may have a variable horizontal cross-sectional shape that decreases in area with a vertical distance from the substrate 8 as illustrated in FIG. 2B. Accordingly, the sidewall of each ovonic threshold switching material portion 152 may have a negative taper angle α as illustrated in FIG. 2A, or may have a positive taper angle β as illustrated in FIG. 2B. As used herein, a positive taper angle is a taper angle that causes a structure become gradually narrower with an increase in an upward vertical distance (i.e., a vertical distance from an underlying horizontal plane), and a negative taper angle is a taper angle that causes a structure to become gradually wider with an increase in the upward vertical distance.

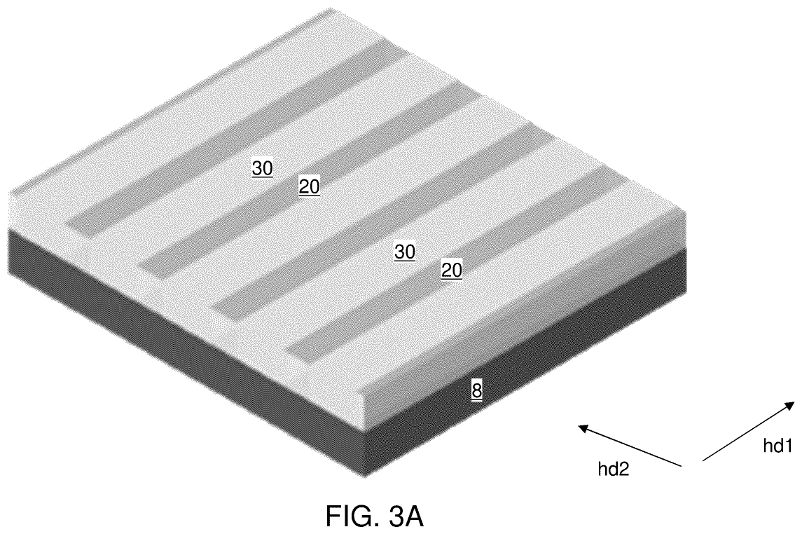

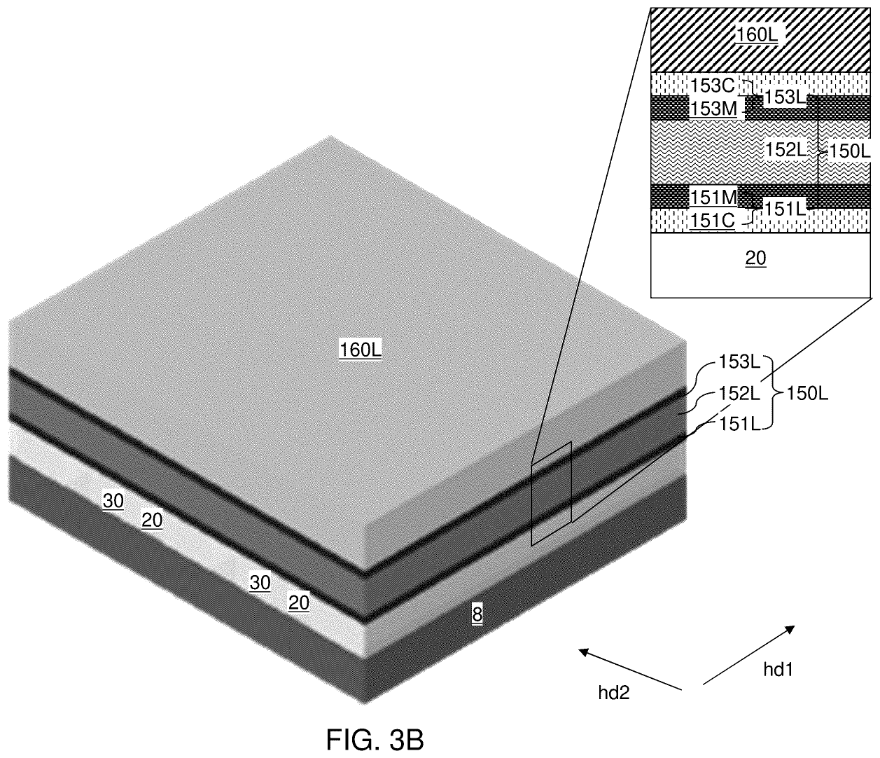

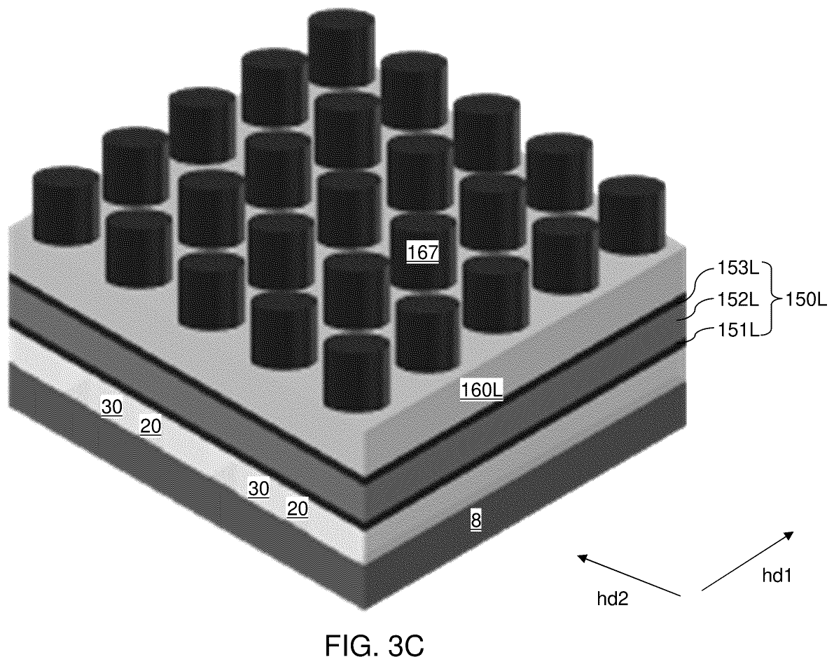

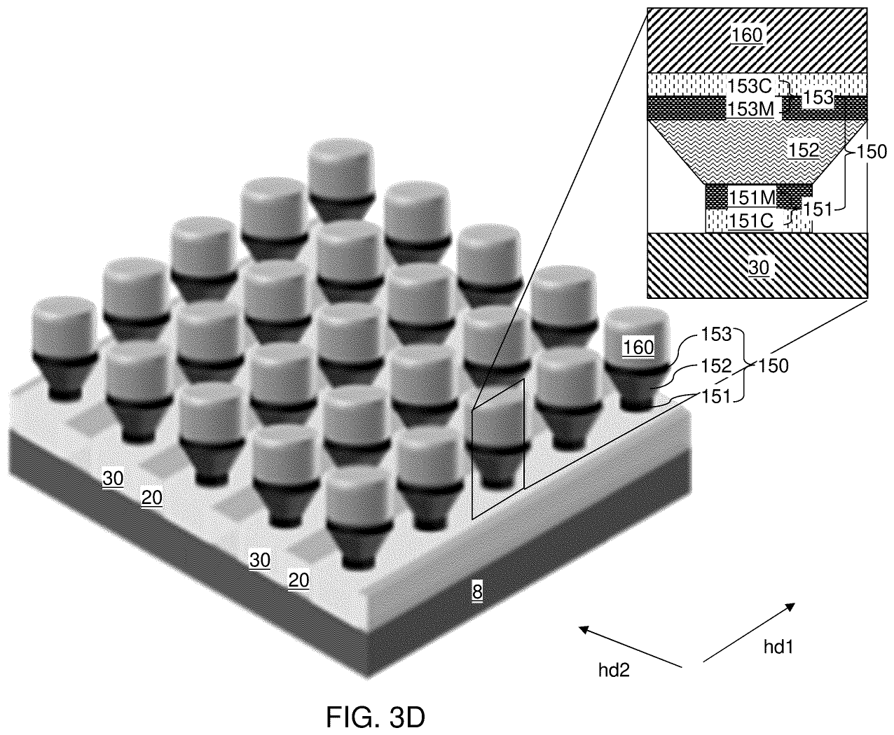

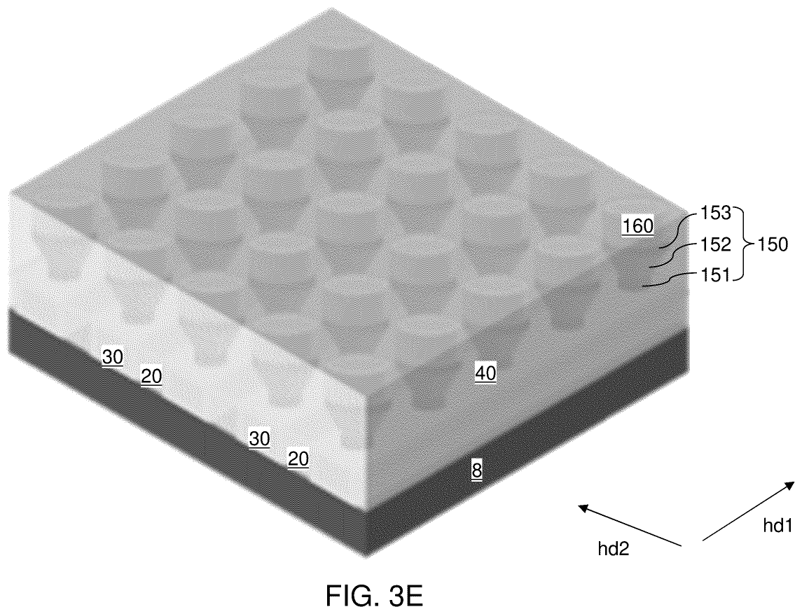

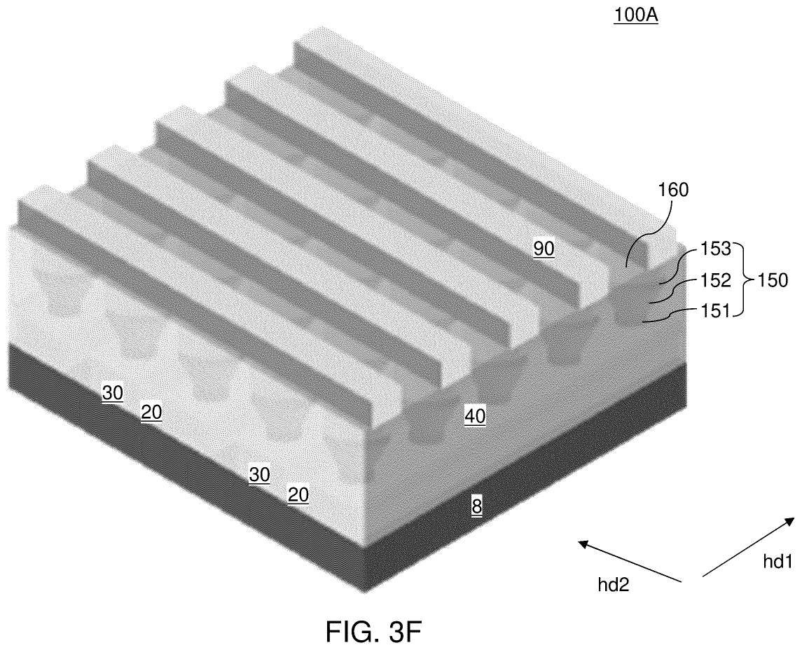

Referring to FIGS. 3A-3F, a first exemplary structure is illustrated during formation of the two-dimensional array 100A of ovonic memory cells 180 of FIG. 2A according to the first embodiment of the present disclosure.

Referring to FIG. 3A, the first exemplary structure includes a substrate 8 having an insulating top surface. The substrate 8 may comprise a combination of a handle substrate (not expressly shown) and an insulating cap layer (not expressly shown). Alternatively, the substrate 8 may comprise a semiconductor substrate (such as a commercially available silicon wafer), semiconductor devices (such as field effect transistors of the driver circuit) formed on the semiconductor substrate, and metal interconnect structures embedded in dielectric material layers overlying the semiconductor devices and providing electrical connection among the semiconductor devices and between the semiconductor devices and the array 100A of ovonic memory cells 180 to be subsequently formed.

First electrically conductive line 30 can be formed on an insulating top surface of the substrate 8. In one embodiment, the first electrically conductive lines 30 can be formed by depositing and patterning a first electrically conductive layer over the insulating top surface of the substrate 8. An insulating material can be deposited between neighboring pairs of first electrically conductive lines 30 and then planarized to form first insulating rails 20.

Alternatively, the first electrically conductive lines 30 may be formed by a damascene process which includes depositing an insulating matrix layer over the substrate 8, patterning the insulating matrix layer to form first line trenches that laterally extend along the first horizontal direction hd1, filling the first line trenches with at least one electrically conductive material, and removing portions of the electrically conductive material from above the horizontal plane including the top surface of the insulating matrix layer. Remaining portions of the at least one electrically conductive material filing the first line trenches constitute the first electrically conductive lines 30. The remaining portions of the insulating matrix layer comprise first insulating rails 20.

The width of the first electrically conductive lines 30 may be in a range from 20 nm to 300 nm, although lesser and greater widths may also be employed. The spacing between neighboring pairs of first electrically conductive lines 30 may be in a range from 30 nm to 300 nm, although lesser and greater spacings may also be employed. In one embodiment, the first electrically conductive lines 30 may function as word lines for the first-tier ovonic memory array 102.

Referring to FIG. 3B, a stack of blanket (unpatterned) layers can be deposited over a laterally alternating sequence of first electrically conductive lines 30 and first insulating rails 20. The stack of blanket layers comprise, for example, a first electrode material layer 151L, an ovonic threshold switching material layer 152L, a second electrode material layer 153L, and an optional metallic hard mask layer 160L. The combination of the first electrode material layer 151L, the ovonic threshold switching material layer 152L, and the second electrode material layer 153L is herein referred to as an ovonic memory layer 150L.

The first electrode material layer 151L includes at least one material that may be employed for first electrodes (such as the first electrodes 151 illustrated in FIGS. 2A and 2B). The ovonic threshold switching material layer 152L includes an ovonic threshold switching material. The second electrode material layer 153L includes at least one material that may be employed second electrodes (such as the second electrodes 153 illustrated in FIGS. 2A and 2B).

In one embodiment, the first electrode material layer 151L may optionally comprise a layer stack including at least one of a first carbon-based electrode material layer 151C and a first metallic material layer 151M formed on the first carbon-based electrode material layer 151C. In one embodiment, the second electrode material layer 153L may optionally comprise a layer stack including at least one of a second metallic material layer 153M and a second carbon-based electrode material layer 153C formed on the second metallic material layer 153M. In another embodiment, the first and/or the second metallic material layers (151M, 153M) may be omitted and the first and second electrode material layers (151L, 153L) may include only the respective first and second carbon-based electrode material layers (151C, 153C).

The first carbon-based electrode material layer 151C and the second carbon-based electrode material layer 153C within the-level material layers can include a respective carbon-based conductive material including carbon atoms at an atomic concentration greater than 50%. In one embodiment, the first carbon-based electrode material layer 151C and the second carbon-based electrode material layer 153C may include carbon atoms at an atomic concentration in a range from 50% to 100%, such as from 70% to 100% and/or from 80% to 100%. In one embodiment, each of first carbon-based electrode material layer 151C and the second carbon-based electrode material layer 153C comprises a respective material selected from diamond-like carbon (DLC), a carbon nitride material, and a carbon-rich conductive compound of carbon atoms and non-carbon atoms. Each of the first carbon-based electrode material layer 151C and the second carbon-based electrode material layer 153C may have a respective thickness in a range from 3 nm to 300 nm, although lesser and greater thicknesses may also be employed.

The first metallic material layer 151M and the second metallic material layer 153M can include a respective metallic material having electrical conductivity that is greater than the electrical conductivity of the carbon-based conductive materials of the first carbon-based electrode material layer 151C and the second carbon-based electrode material layer 153C. In one embodiment, the first metallic material layer 151M comprises a metallic material having electrical conductivity that is at least 10 times (which may be at least 30 times and/or at least 100 times and/or at least 1,000 times) the electrical conductivity of the carbon-based conductive material of first carbon-based electrode material layer 151C, and the second metallic material layer 153M comprises a second metallic material having electrical conductivity that is at least 10 times (which may be at least 30 times and/or at least 100 times and/or at least 1,000 times) the electrical conductivity of the carbon-based conductive material of the second carbon-based electrode material layer 153C.

Generally, each of the first metallic material layer 151M and the second metallic material layer 153M may comprise, and/or may consist essentially of, a high-conductivity metallic material that has a high electrical conductivity, and thus, is capable of functioning as a current-spreading material that prevents concentration of electrical current in the ovonic threshold switching material of the ovonic threshold switching material layer 152L. In one embodiment, the first metallic material layer 151M and/or the second metallic material layer 153M may comprise, and/or may consist essentially of, an elemental metal, a conductive metallic carbide, or a conductive metallic nitride. In one embodiment, the first metallic material layer 151M and/or the second metallic material layer 153M may comprise, and/or may consist essentially of, a respective elemental metal selected from ruthenium, niobium, molybdenum, tantalum, tungsten, or rhenium. In one embodiment, the first metallic material layer 151M and/or the second metallic material layer 153M may comprise, and/or may consist essentially of, a conductive metallic carbide, such as tungsten carbide. In one embodiment, the first metallic material layer 151M and/or the second metallic material layer 153M may comprise, and/or may consist essentially of, a conductive metallic nitride, such as tungsten nitride, titanium nitride, or tantalum nitride.

In one embodiment, the ovonic threshold switching material layer 152L can include an ovonic threshold switching material which exhibits non-linear electrical behavior. As used herein, an ovonic threshold switching material refers to a material that displays a non-linear resistivity curve under an applied external bias voltage such that the resistivity of the material decreases with the absolute magnitude of the applied external bias voltage greater than the absolute value of the threshold voltage. In one embodiment, the ovonic threshold switch material can comprise a chalcogenide material. The chalcogenide material may be a GeSeAs alloy, a GeSeAsTe alloy, a GeTeAs alloy, a GeSeTe alloy, a GeSe alloy, a SeAs alloy, a AsTe alloy, a GeTe alloy, a SiTe alloy, a SiAsTe alloy, or SiAsSe alloy. The chalcogenide material may be undoped or doped with at least one of N, O, C, P, Ge, As, Te, Se, In, or Si.

The metallic hard mask layer 160L comprises at least one electrically conductive material that may subsequently function as a hard mask material. The metallic hard mask layer 160L may comprise at least one metallic nitride material and/or at least one elemental metal. For example, the metallic hard mask layer 160L may comprise and/or may consist essentially of TiN, TaN, WN, MON, Ti, Ta, W, Mo, Co, Ru, etc.

Referring to FIG. 3C, a photoresist layer can be applied over the metallic hard mask layer 160L, and can be lithographically patterned to form a two-dimensional array of discrete photoresist material portions 167. The two-dimensional array of discrete photoresist material portions 167 may have a periodic pitch along the second horizontal direction hd2 that is the same as the pitch of the first electrically conductive lines 30 along the second horizontal direction hd2.

Referring to FIG. 3D, an anisotropic etch process can be performed to transfer the pattern of the two-dimensional array of discrete photoresist material portions 167 through the metallic hard mask layer 160L. The metallic hard mask layer 160L can be patterned into a two-dimensional array of metallic pillar structures 160. In one embodiment, the metallic pillar structures 160 may have a circular cylindrical shape or an elliptical cylindrical shape.

The anisotropic etch process may be continued with a suitable change in the etch chemistry to etch unmasked portions of the second electrode material layer 153L. The second electrode material layer 153L is patterned into a two-dimensional array of second electrodes 153. Each second electrode 153 may comprise a layer stack of a second metallic material layer 153M and an second carbon-based electrode material layer 153C overlying the second metallic material layer 153M. The two-dimensional array of discrete photoresist material portions 167 can be subsequently removed, for example, by ashing.

The ovonic threshold switching material layer 152L can be patterned by transferring the pattern in the two-dimensional array of metallic pillar structures 160 through the ovonic threshold switching material layer 152L. In one embodiment, the pattern in the two-dimensional array of metallic pillar structures 160 can be transferred through the ovonic threshold switching material layer 152L by performing an ion beam etching process. In one embodiment, a two-step ion-beam etching (IBE) process may be employed to pattern the ovonic threshold switching material layer 152L into a two-dimensional array of ovonic threshold switching material portions 152 each having a shape of a respective inverted conical frustum.

The two-step IBE process comprises a first IBE process (also referred to as a low-tilt-angle high-energy IBE process) in which a first high energy ion beam impinges onto the ovonic threshold switching material layer 152L at a first tilt angle relative to a vertical direction perpendicular to the top surface of the substrate 8. The first tilt angle may be in a range from 0 degree to 35 degrees, and the direction of the ion beam may be gradually azimuthally rotated by 360 degrees around the vertical direction during the first IBE process. In the first IBE process, the ion beam penetrates through the entire thickness of the ovonic threshold switching material layer 152L. The two-step IBE process further comprises a second IBE process (also referred to as a high-tilt-angle low-energy IBE process) in which a second lower energy ion beam than the first ion beam impinges onto the patterned discrete portions of the ovonic threshold switching material layer 152L at a second tilt angle relative to the vertical direction. The second tilt angle may be higher than the first tilt angle. For example, the second title angle may be in a range from 60 degrees to 80 degrees, and the direction of the ion beam may be gradually azimuthally rotated by 360 degrees around the vertical direction during the second IBE process. The patterned discrete portions of the ovonic threshold switching material layer 152L can be patterned into the shapes of the inverted frustums during the second IBE process to form the two-dimensional array of ovonic threshold switching material portions 152. The high tilt angle prevents re-deposition of etched materials from the ovonic threshold switching material layer 152L.

In an alternative embodiment, the inverted frustrum shaped ovonic threshold switching material portions 152 may be formed by a one step reactive ion etching process which includes undercutting. In other words, the reactive ion etching process conditions are selected to form the ovonic threshold switching material portions 152 with inclined sidewalls, as shown in FIG. 3D.

Another anisotropic etch process may be performed to etch unmasked portions of the first electrode material layer 151L. The combination of the arrays of the metallic pillar structures 160, the second electrodes 153, and the ovonic threshold switching material portions 152 may be employed as an etch mask for patterning the first electrode material layer 151L. The first electrode material layer 151L is patterned into a two-dimensional array of first electrodes 151. Each first electrode 151 may comprise a layer stack of a first metallic material layer 151M and a first carbon-based electrode material layer 151C underlying the first metallic material layer 151M.

Referring to FIG. 3E, at least one dielectric fill material, such as a combination of a silicon nitride liner and a silicon oxide fill material layer, can be deposited in the gaps among the arrays of the metallic pillar structures 160, the second electrodes 153, the ovonic threshold switching material portions 152, and the first electrodes 151. A suitable reflow process may optionally be performed to reduce, and/or eliminate, voids in the at least one dielectric fill material. A planarization process, such as a chemical mechanical polishing process, may be performed to remove portions of the at least one dielectric fill material from above the horizontal plane including the top surfaces of the metallic pillar structures 160. The remaining portion of the at least one dielectric fill material constitutes a dielectric fill material layer 40 that laterally surrounds the arrays of the metallic pillar structures 160, the second electrodes 153, the ovonic threshold switching material portions 152, and the first electrodes 151.

Referring to FIG. 3F, second electrically conductive lines 90 can be formed on the physically exposed surfaces of the metallic pillar structures 160. Each second electrically conductive line 90 can laterally extend along the second horizontal direction hd2, and may contact a respective column of metallic pillar structures 160 that extends along the second horizontal direction hd2. The pitch of the second electrically conductive lines 90 along the first horizontal direction hd1 may be the same as the pitch of the two-dimensional array of metallic pillar structures 160 along the first horizontal direction hd1. An insulating material (not shown) can be deposited between neighboring pairs of second electrically conductive lines 90 to form second insulating rails (not shown).

Alternatively, the second electrically conductive lines 90 may be formed by a damascene process which includes depositing an insulating matrix layer, patterning the insulating matrix layer to form second line trenches that laterally extend along the second horizontal direction hd2, filling the second line trenches with at least one electrically conductive material, and removing portions of the electrically conductive material from above the horizontal plane including the top surface of the insulating matrix layer. Remaining portions of the at least one electrically conductive material filing the second line trenches constitute the second electrically conductive lines 90. The remaining portions of the insulating matrix layer comprise second insulating rails (not shown).

The second electrically conductive lines 90 laterally extend along the second horizontal direction hd2, and each second electrode 153 in the two-dimensional array of memory cells contacts a respective one of the second electrically conductive lines 90. The second electrically conductive lines 90 may function as bit lines in the first-tier ovonic memory array 102.

In one embodiment, each second electrode 153 contacts a bottom surface of metallic pillar structure 160. Each metallic pillar structure 160 has a different area than a bottom surface of an underlying ovonic threshold switching material portion 152. In one embodiment, for each ovonic threshold switching material portion 152, a tapered surface of the ovonic threshold switching material portion 152 continuously extends from a top surface of the first electrode 151 to a bottom surface of the second electrode 153. In one embodiment, the ovonic threshold switching material portion 152 has a variable horizontal cross-sectional area that increases with a vertical distance from a horizontal plane including the top surfaces of the first electrodes 151. In one embodiment, the ovonic threshold switching material portions 152 have a respective circular or oval-shaped horizontal cross-sectional shape.

In one embodiment, each first electrode 151 comprises a layer stack including a first carbon-based electrode material layer 151C and a first metallic material layer 151M. In one embodiment, each second electrode 153 comprises a layer stack including a second metallic material layer 153M and a second carbon-based electrode material layer 153C. In one embodiment, each first electrode 151 comprises a first metallic surface in contact with a bottom surface of an ovonic threshold switching material portion 152.

In one embodiment, a two-dimensional array 100A of memory cells 180 is provided. Each of the memory cells comprises a vertical stack of a first electrode 151, an ovonic threshold switching material portion 152, and a second electrode 153. Each of the ovonic threshold switching material portions 152 in the two-dimensional array 100A of memory cells 180 has a respective shape of a frustum (e.g., inverted frustrum in this embodiment). In one embodiment, the memory device further comprises first electrically conductive lines 30 laterally extending along a first horizontal direction hd1. Each first electrode 151 in the two-dimensional array of memory cells contacts a respective portion of the first electrically conductive lines 30.

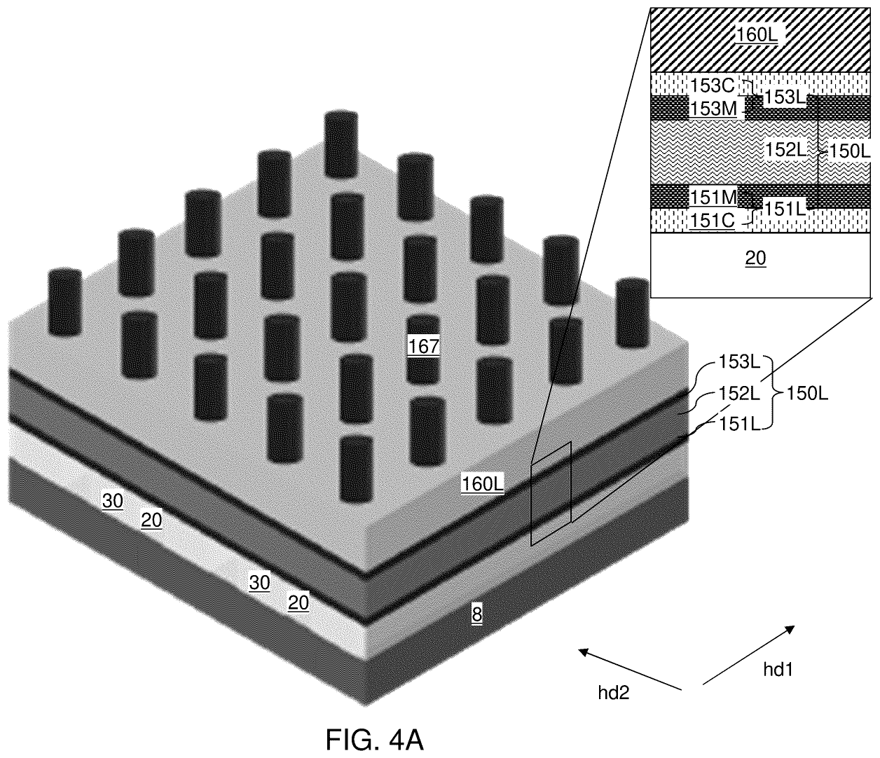

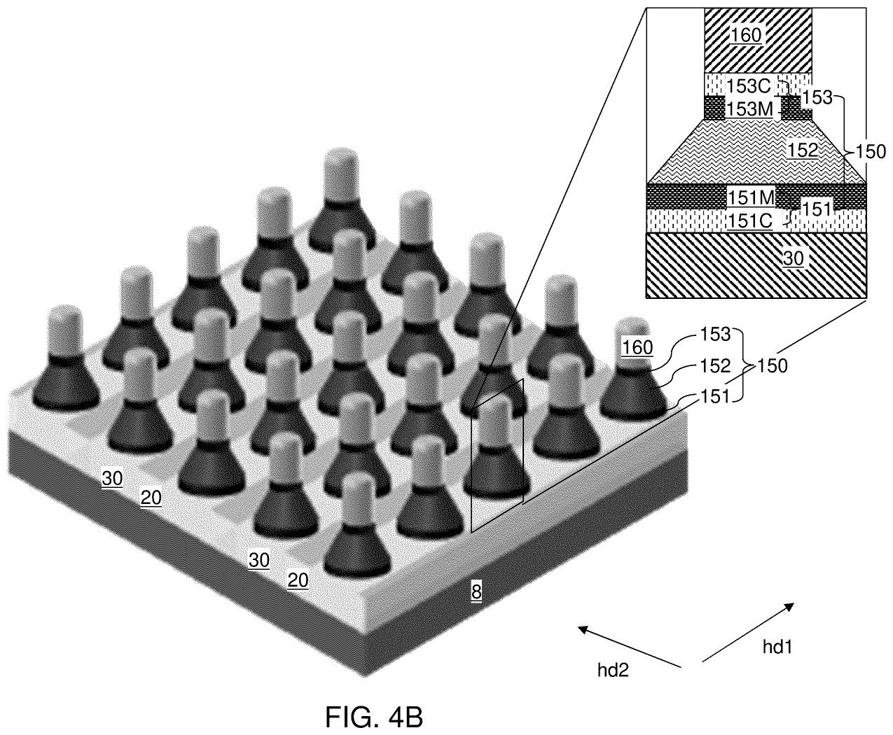

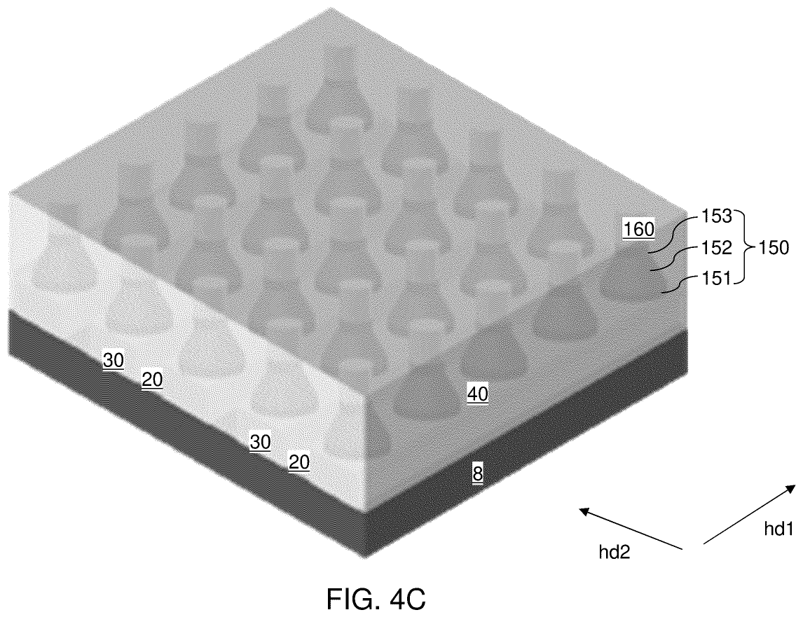

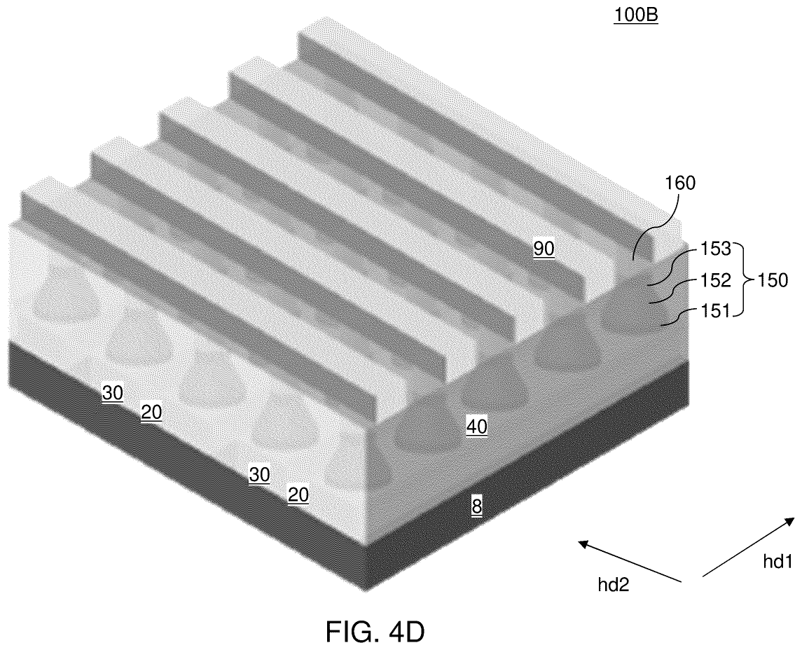

FIGS. 4A-4D are sequential perspective views of a second exemplary structure during formation of the two-dimensional array 100B of ovonic memory cells 180 of FIG. 2B according to the second embodiment of the present disclosure.

Referring to FIG. 4A, the second exemplary structure can be derived from the first exemplary structure illustrated in FIG. 3C by reducing the size of each discrete photoresist material portion 167 in the two-dimensional array of discrete photoresist material portions 167. In one embodiment, a maximum lateral dimension (such as a diameter) of each discrete photoresist material portion 167 may be in a range from 10 nm to 40 nm, although lesser and greater maximum lateral dimensions may also be employed.

Referring to FIG. 4B, an anisotropic etch process can be performed to transfer the pattern of the two-dimensional array of discrete photoresist material portions 167 through the metallic hard mask layer 160L. The metallic hard mask layer 160L can be patterned into a two-dimensional array of metallic pillar structures 160. In one embodiment, the metallic pillar structures 160 may have a circular cylindrical shape or an elliptical cylindrical shape.

The anisotropic etch process may be continued with a suitable change in the etch chemistry to etch unmasked portions of the second electrode material layer 153L. The second electrode material layer 153L is patterned into a two-dimensional array of second electrodes 153. Each second electrode 153 may comprise a layer stack of a second metallic material layer 153M and a second carbon-based electrode material layer 153C overlying the second metallic material layer 153M. The two-dimensional array of discrete photoresist material portions 167 can be subsequently removed, for example, by ashing.

The ovonic threshold switching material layer 152L can be patterned by transferring the pattern in the two-dimensional array of metallic pillar structures 160 through the ovonic threshold switching material layer 152L. In one embodiment, the pattern in the two-dimensional array of metallic pillar structures 160 can be transferred through the ovonic threshold switching material layer 152L by performing an ion beam etching process.

According to an aspect of the present disclosure, a single-step ion-beam etching (IBE) process may be employed to pattern the ovonic threshold switching material layer 152L into a two-dimensional array of ovonic threshold switching material portions 152 each having a shape of a respective conical frustum. In the single-step IBE process, a high energy ion beam impinges onto the ovonic threshold switching material layer 152L along a downward vertical direction or at a small tilt angle (which may be less than 35 degrees) relative to the downward vertical direction. In case the ion beam has a non-zero tilt angle, the direction of the ion beam may be gradually azimuthally rotated by 360 degrees around the vertical direction during the single-step IBE process. The single-step IBE process generates tapered sidewalls with a positive taper angle, i.e., an angle that causes a bottom region of each ovonic threshold switching material portion 152 to have a greater width than a top region of each ovonic threshold switching material portion 152.

In an alternative embodiment, the frustrum shaped ovonic threshold switching material portions 152 may be formed by a one-step reactive ion etching process which produces sidewall inhibitor deposition. In other words, the reactive ion etching process conditions are selected to form the ovonic threshold switching material portions 152 with tapered sidewalls, as shown in FIG. 4B.

Another anisotropic etch process may be performed to etch unmasked portions of the first electrode material layer 151L. The combination of the arrays of the metallic pillar structures 160, the second electrodes 153, and the ovonic threshold switching material portions 152 may be employed as an etch mask for patterning the first electrode material layer 151L. The first electrode material layer 151L is patterned into a two-dimensional array of first electrodes 151. Each first electrode 151 may comprise a layer stack of a first metallic material layer 151M and a first carbon-based electrode material layer 151C underlying the first metallic material layer 151M.

In the second embodiment, for each ovonic threshold switching material portion 152, a tapered surface of the ovonic threshold switching material portion 152 continuously extends from a top surface of the first electrode 151 to a bottom surface of the second electrode 153. The ovonic threshold switching material portion 152 has a variable horizontal cross-sectional area that decreases with a vertical distance from a horizontal plane including the top surfaces of the first electrodes 151. In one embodiment, the ovonic threshold switching material portions 152 have a respective circular or oval-shaped horizontal cross-sectional shape. Thus, in the second embodiment, each of the ovonic threshold switching material portions 152 in the two-dimensional array of memory cells has a respective shape of a right-side-up frustum.

Referring to FIG. 4C, at least one dielectric fill material, such as a combination of a silicon nitride liner and a silicon oxide fill material layer, can be deposited in the gaps among the arrays of the metallic pillar structures 160, the second electrodes 153, the ovonic threshold switching material portions 152, and the first electrodes 151. A suitable reflow process may optionally be performed to reduce, and/or eliminate, voids in the at least one dielectric fill material. A planarization process, such as a chemical mechanical polishing process, may be performed to remove portions of the at least one dielectric fill material from above the horizontal plane including the top surfaces of the metallic pillar structures 160. The remaining portion of the at least one dielectric fill material constitutes a dielectric fill material layer 40 that laterally surrounds the arrays of the metallic pillar structures 160, the second electrodes 153, the ovonic threshold switching material portions 152, and the first electrodes 151.

Referring to FIG. 4D, the second electrically conductive lines 90 can be formed on the physically exposed surfaces of the metallic pillar structures 160. Each second electrically conductive line 90 can laterally extend along the second horizontal direction hd2, and may contact a respective column of metallic pillar structures 160 that extends along the second horizontal direction hd2. The pitch of the second electrically conductive lines 90 along the first horizontal direction hd1 may be the same as the pitch of the two-dimensional array of metallic pillar structures 160 along the first horizontal direction hd1. An insulating material (not shown) can be deposited between neighboring pairs of second electrically conductive lines 90 to form second insulating rails (not shown). Alternatively, the second electrically conductive lines 90 may be formed by the above described damascene process. The second electrically conductive lines 90 laterally extend along the second horizontal direction hd2, and each second electrode 153 in the two-dimensional array of memory cells 180 contacts a respective one of the second electrically conductive lines 90.

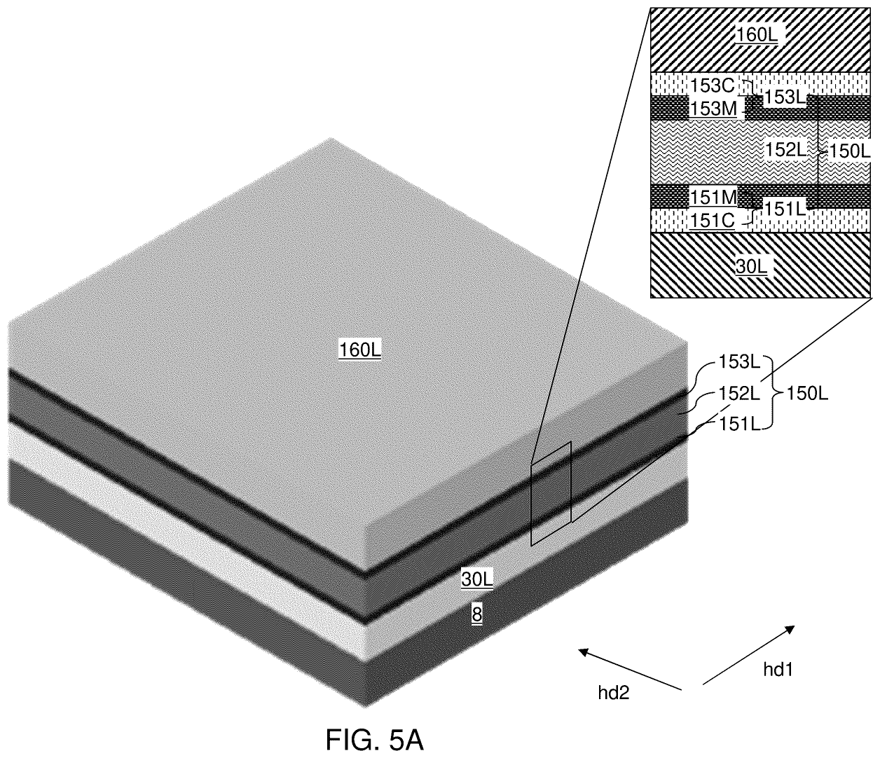

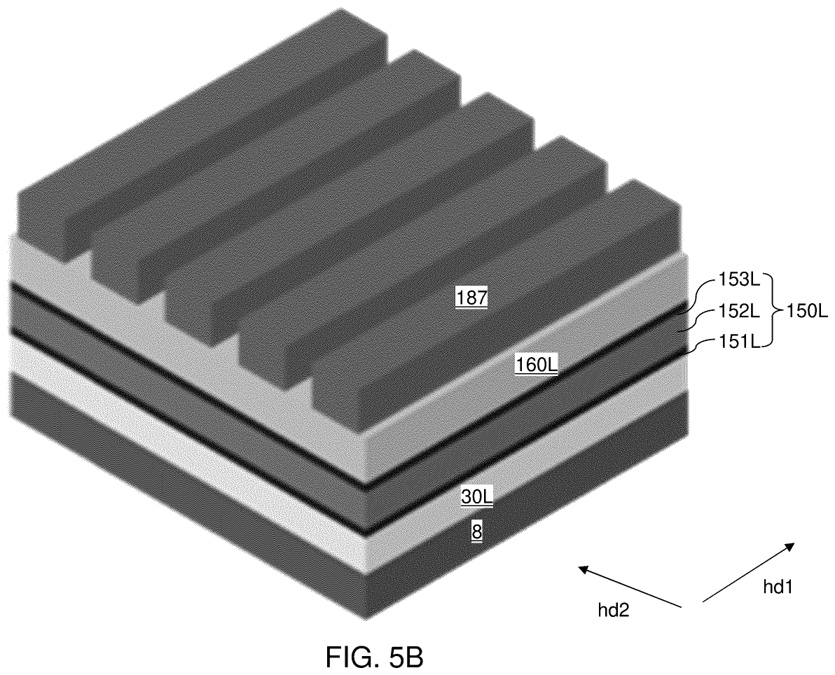

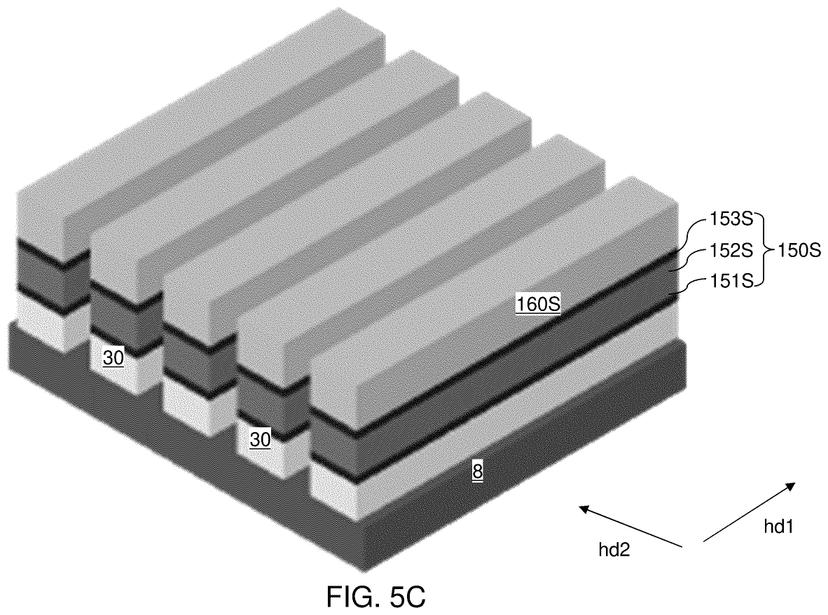

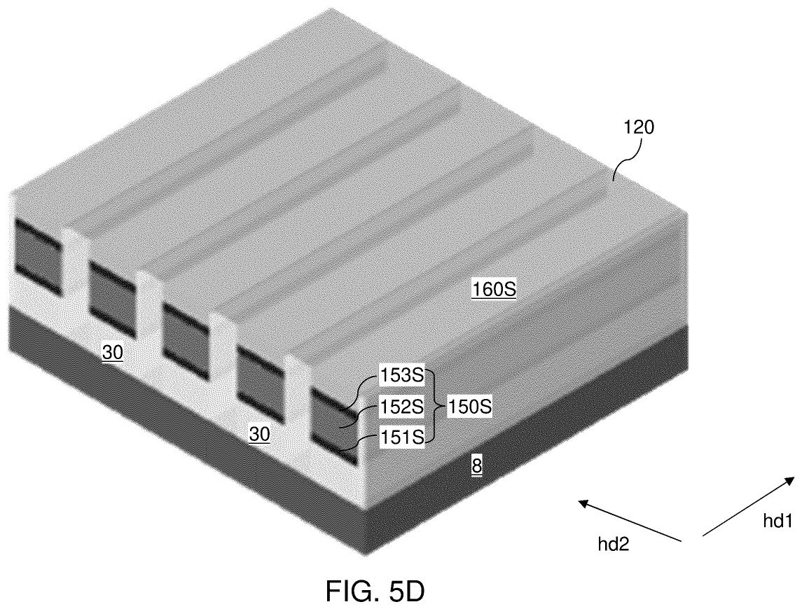

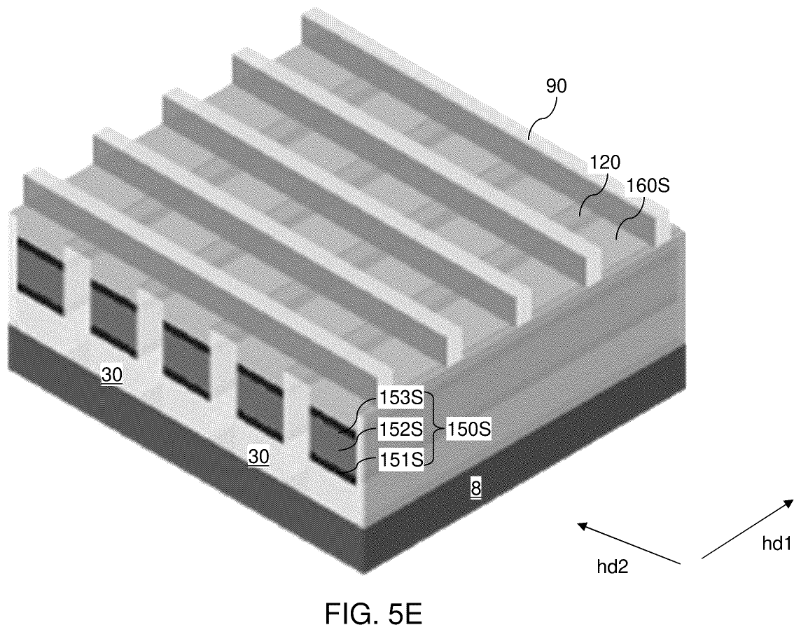

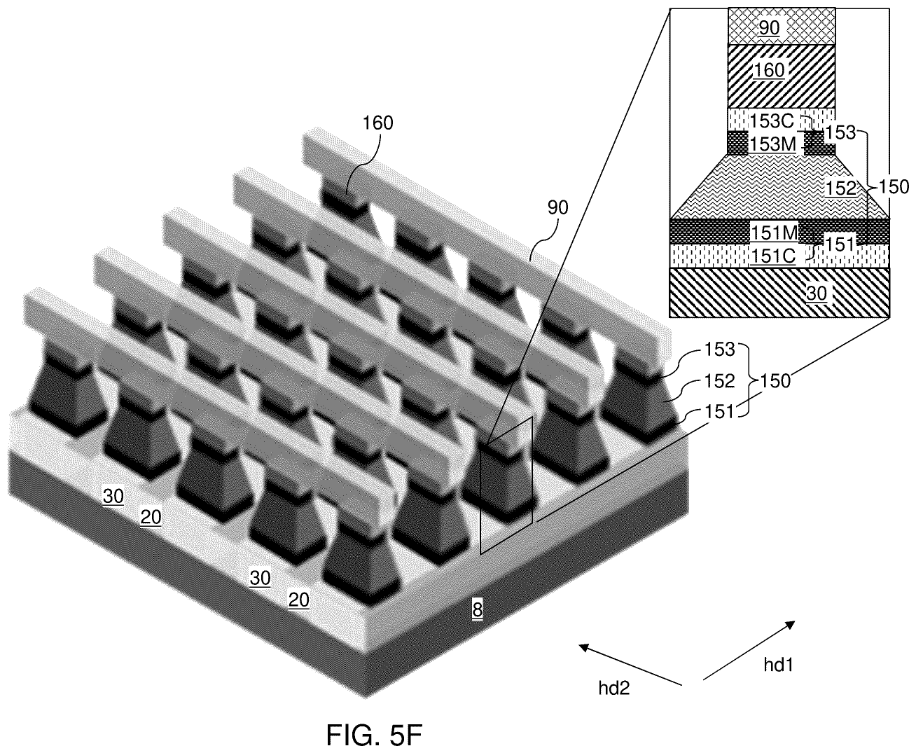

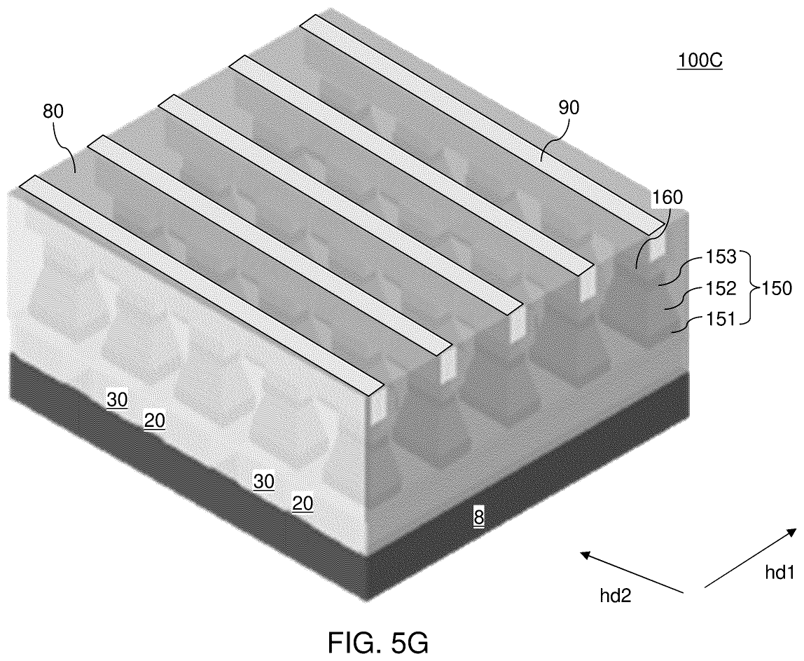

FIGS. 5A-5G are sequential perspective views of a third exemplary structure during formation of a two-dimensional array 100C of ovonic memory cells 180 according to the third embodiment of the present disclosure.

Referring to FIG. 5A, the third exemplary structure comprises a substrate 8 having an insulating top surface, a first electrically conductive layer 30L, an ovonic memory layer 150L, and a metallic hard mask layer 160L. The first electrically conductive layer 30L may have the same material composition and the same thickness as the first electrically conductive lines 30 discussed above. The first electrically conductive layer 30L may be deposited as a blanket layer, i.e., as an unpatterned material layer.

Referring to FIG. 5B, a photoresist layer can be applied over the metallic hard mask layer 160L, and can be lithographically patterned with a line-and-space pattern to form a one-dimensional array of photoresist rails 187. The one-dimensional array of photoresist rails 187 may have the same pattern as the pattern of the first electrically conductive lines 30 discussed above.

Referring to FIG. 5C, a first anisotropic etch process can be performed to transfer the pattern of the one-dimensional array of photoresist rails 187 through the metallic hard mask layer 160L. The metallic hard mask layer 160L can be patterned into a one-dimensional array of metallic strip structures 160S. The metallic strip structures 160S may have a same width throughout along the second horizontal direction hd2.

The first anisotropic etch process may be continued with a suitable change in the etch chemistry to etch unmasked portions of the second electrode material layer 153L. The second electrode material layer 153L is patterned into a one-dimensional array of second electrode strips 153S. Each second electrode strip 153S may comprise a layer stack of an optional second metallic material strip and a second carbon-based electrode material strip overlying the second metallic material layer strip. The one-dimensional array of photoresist rails 187 can be subsequently removed, for example, by ashing.

The ovonic threshold switching material layer 152L can be patterned by transferring the pattern in the one-dimensional array of metallic strip structures 160S through the ovonic threshold switching material layer 152L. In one embodiment, the pattern in the one-dimensional array of metallic strip structures 160S can be transferred through the ovonic threshold switching material layer 152L by performing an ion beam or a reactive ion etching process.

According to an aspect of the present disclosure, the ion beam etching process may comprise the two-step IBE process or a RIE process with undercutting described with reference to FIG. 3D, or a single-step IBE process or a RIE process described with reference to FIG. 4B. Patterned portions of the ovonic threshold switching material layer 152L comprise ovonic threshold switching material strips 152S. Accordingly, the vertical cross-sectional profile of each ovonic threshold switching material portion 152 along a vertical plane that is perpendicular to the first horizontal direction hd1 may have a shape of an inverted trapezoid having a greater lateral extent at top than at bottom, or may have a shape of an upright trapezoid having a lesser lateral extent at top than at bottom.

A second anisotropic etch process may be performed to etch unmasked portions of the first electrode material layer 151L. The combination of the arrays of the metallic strip structures 160S, the second electrode strips 153S, and the ovonic threshold switching material strips 152S may be employed as an etch mask for patterning the first electrode material layer 151L. The first electrode material layer 151L is patterned into a one-dimensional array of first electrode strips 151S. Each first electrode strip 151S may comprise a layer stack of an optional first metallic material strip and a first carbon-based electrode material strip underlying the second metallic material strip. Each contiguous combination of a first electrode strips 151S, an ovonic threshold switching material strip 152S, and a second electrode strip 153S constitutes an ovonic memory strip 150S.

The second anisotropic etch process may be continued with a change in the etch chemistry to etch unmasked portions of the first electrically conductive layer 30L. The first electrically conductive layer 30L may be patterned into a one-dimensional array of first electrically conductive lines 30.

Referring to FIG. 5D, a dielectric fill material may be deposited in the gaps between vertical stacks of a first electrically conductive line 30, a first electrode strip 151S, an ovonic threshold switching material strip 152S, a second electrode strip 153S, and a metallic strip structure 160S. The dielectric fill material may comprise, for example, a combination of a silicon nitride liner and a silicon oxide fill material. Portions of the dielectric fill material that overlies the horizontal plane including the top surfaces of the metallic strip structures 160S can be removed by performing a planarization process such as a chemical mechanical polishing (CMP) process. The remaining portions of the dielectric fill material comprise a first dielectric fill material layer 120 including a plurality of dielectric fill material rails that are laterally spaced apart along the second horizontal direction hd2.

Referring to FIG. 5E, second electrically conductive lines 90 can be formed on the physically exposed surfaces of the metallic pillar structures 160. Each second electrically conductive line 90 can laterally extend along the second horizontal direction hd2. The pitch of the second electrically conductive lines 90 along the first horizontal direction hd1 may be the same as the pitch of a two-dimensional array of metallic pillar structures 160 to be subsequently formed along the first horizontal direction hd1.

Referring to FIG. 5F, an anisotropic etch process can be performed to anisotropically etch portions of the first dielectric fill material layer 120, the metallic strip structures 160S, and the second electrode strips 153S employing the second electrically conductive lines 90 as an etch mask structure. The one-dimensional array of metallic strip structures 160S is patterned into a two-dimensional array of metallic pillar structures 160 having a respective rectangular horizontal cross-sectional shape. The one-dimensional array of second electrode strips 153S is patterned into a two-dimensional array of second electrodes 153 having a respective rectangular horizontal cross-sectional shape.

An ion beam etch process can be performed to pattern the one-dimensional array of ovonic threshold switching material strips 152S into a two-dimensional array of ovonic threshold switching material portions 152. According to an aspect of the present disclosure, the ion beam etching process may comprise the two-step IBE process described with reference to FIG. 3D, or a single-step IBE process described with reference to FIG. 4B. If the ion beam etching process employed at the processing steps of FIG. 5C comprises a two-step IBE process, the ion beam etching process employed at the processing steps of FIG. 5F comprises another two-step IBE process. If the ion beam etching process is employed at the processing steps of FIG. 5C comprises a single-step IBE process, the ion beam etching process employed at the processing steps of FIG. 5F comprises another single-step IBE process. Alternatively, the etching process employed at the processing steps of FIG. 5C comprises an RIE process with an undercut, then the etching process employed at the processing steps of FIG. 5F comprises another RIE process with the undercut.

Patterned portions of the one-dimensional array of ovonic threshold switching material strips 152S comprise a two-dimensional array of ovonic threshold switching material portions 152. Accordingly, the vertical cross-sectional profile of each ovonic threshold switching material portion 152 along a vertical plane that is perpendicular to the first horizontal direction hd1 may have a shape of an inverted trapezoid, and the vertical cross-sectional profile of each ovonic threshold switching material portion 152 along a vertical plane that is perpendicular to the second horizontal direction hd2 may have a shape of an inverted trapezoid, which forms an inverted pyramidal frustrum. Alternatively, the vertical cross-sectional profile of each ovonic threshold switching material portion 152 along a vertical plane that is perpendicular to the first horizontal direction hd1 may have a shape of an upright trapezoid having a lesser lateral extent at top than at bottom, and the vertical cross-sectional profile of each ovonic threshold switching material portion 152 along a vertical plane that is perpendicular to the second horizontal direction hd2 may have a shape of an upright trapezoid having a lesser lateral extent at top than at bottom which forms a right-side-up pyramidal frustrum. Remaining portions of the first dielectric fill material layer 120 located between the first electrically conductive lines 30 comprise the first insulating rails 20. In the third embodiment, the ovonic threshold switching material portions 152 may have a rectangular horizontal cross-sectional shape that changes in size along the vertical direction.

Referring to FIG. 5G, at lest one insulating fill material can be deposited in the voids underlying the horizontal plane including the top surfaces of the second electrically conductive lines 90. The at least one insulating fill material may comprise a combination of a silicon nitride liner and a silicon oxide fill material layer. Excess portions of the at least one insulating fill material can be removed from above the horizontal plane including the top surfaces of the second electrically conductive lines 90 by a planarization process, which may comprise a chemical mechanical polishing (CMP) process. Remaining portions of the at least one insulating fill material constitute an insulating matrix layer 80, which comprises a plurality of insulating material rails that laterally extend along the second horizontal direction hd2 and laterally spaced apart along the first horizontal direction hd1.

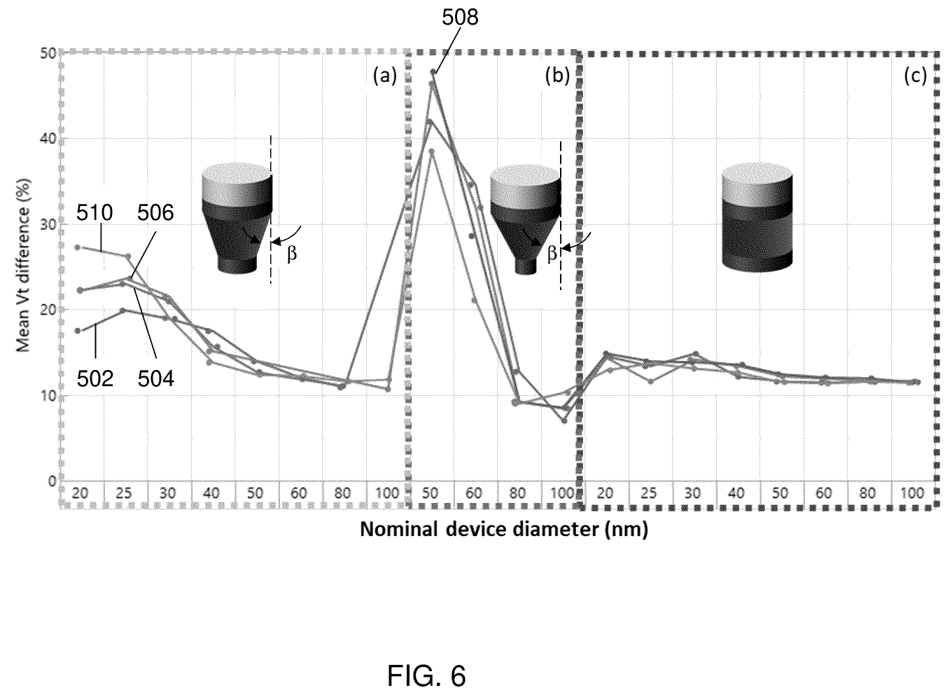

Referring to FIG. 6, data for ΔVth/Vth is illustrated for various shapes of ovonic threshold switching material portions 152. FIG. 6 is a plot of a mean threshold voltage difference (i.e., ΔVth/Vth) versus nominal portion 152 base diameter. In this embodiment, ΔVth is the difference between Vth+/− and Vth+/+, where Vth+/− is the threshold voltage going from a positive voltage pulse (previous pulse) to a negative voltage pulse (i.e., Vth measurement pulse), and Vth+/+ is the threshold voltage going from a positive voltage pulse to another positive voltage pulse. In this case, ΔVth/Vth={(Vth+/−)−(Vth+/+)}/(Vth+/+).

First-type ovonic memory cells 180 of the first embodiment are schematically illustrated in box (a), and the data for ΔVth/Vth for first-type ovonic memory cells 180 having various base (i.e., widest width of element 152) dimensions ranging from 20 nm to 100 nm are also shown in box (a). The first-type ovonic threshold switching material portions 152 may have a negative taper angle α of about 25 degrees.

Second-type ovonic memory cells 180 of the first embodiment are schematically illustrated in box (b), and the data for ΔVth/Vth second-type ovonic memory cells 180 having various base dimensions ranging from 50 nm to 100 nm are also shown in box (b). The second-type ovonic threshold switching material portions 152 may have a negative taper angle α of about 40 degrees.

Third-type ovonic memory cells of a comparative example are schematically illustrated in box (c), and the data for ΔVth/Vth for third-type ovonic memory cell having uniform lateral dimensions ranging from 20 nm to 100 nm are also shown in box (c).

The data plotted in FIG. 6 corresponds to hundreds of memory devices from three different wafers. The data in each box (a), (b) and (c) represents hundreds of memory devices on each wafer. For comparison, all data is plotted together. Lines 502 to 510 correspond to specific resistor lengths of resistors that are formed in electrical series with the memory devices. Line 502 corresponds to resistors having a predetermined length. Line 504 corresponds to a resistor having length that is 3.2/2 times the predetermined length of the resistor represented by line 502. Line 506 corresponds to a resistor having length that is two times the predetermined length of the resistor represented by line 502. Line 508 corresponds to a resistor having length that is 5/2 times the predetermined length of the resistor represented by line 502. Line 510 corresponds to a resistor having length that is four times the predetermined length of the resistor represented by line 502.

As shown in FIG. 6, the presence of a taper angle in an ovonic threshold switching material portion 152 can increase the value for ΔVth/Vth and thus increase the memory window for the memory cell 180. ΔVth/Vth values above 15%, such as 18 to 48% may be achieved. Enhancement in the value for ΔVth/Vth is more prominent when the lateral dimension of the neck portion of an ovonic threshold switching material portion 152 is not greater than 60 nm, such as 10 to 30 nm, for example 15 to 25 nm, e.g., about 20 nm, and the taper angle is increased above 30 degrees, such as 35 to 50 degrees. Without wishing to be bound by a particular theory, the neck width of about 10 to 30 nm is roughly comparable to a width of a filament that may be formed through the ovonic threshold switching material portion 152 during programming.

Referring to all drawings and according to various embodiments of the present disclosure, an ovonic memory element 150 includes a first electrode 151, a second electrode 153, and an ovonic threshold switching material portion 152 located between the first electrode and the second electrode. A first surface of the ovonic threshold switching material portion 152 facing the first electrode 151 is wider than an opposing second surface of the ovonic threshold switching material portion facing the second electrode 153.

In one embodiment, the first surface of the ovonic threshold switching material portion 152 contacts the first electrode 151, and the second surface of the ovonic threshold switching material portion 152 contacts the second electrode 153. In one embodiment, the first electrode 151 is located above the second electrode 153. In another embodiment, the first electrode 151 is located below the second electrode 153. In one embodiment, the ovonic threshold switching material portion comprises a chalcogenide material.

In one embodiment, the ovonic threshold switching material portion 152 has a shape of a frustrum (e.g., right-side-up or inverted frustrum). In one embodiment, tapered surface (e.g., sidewall) of the ovonic threshold switching material portion 152 continuously extends from the first electrode 151 to the second electrode 153. In one embodiment, the ovonic threshold switching material portion 152 has a variable horizontal cross-sectional area that decreases with a vertical distance from the second electrode 153 to the first electrode 151.

In the first and second embodiments, the ovonic threshold switching material portion 152 has a circular or oval-shaped horizontal cross-sectional shape. In the third embodiment, the ovonic threshold switching material portion 152 has a rectangular horizontal cross-sectional shape.

In one embodiment, the ovonic threshold switching material portion is configured to store data (i.e., the ovonic memory element 150 is the data storage element located in the OTS-only memory cell 180 which lacks a magnetic or phase change data storage element). In one embodiment, the ovonic memory element has a ΔVth/Vth value of greater than 15%.

In one embodiment, a memory device (e.g., memory cell 180), comprises the ovonic memory element 152, the first electrically conductive line 30 that laterally extends along a first horizontal direction hd1 and electrically connected to the first electrode 151, a second electrically conductive line 90 that laterally extends along a second horizontal direction hd2 and electrically connected to the second electrode 153, and a metallic pillar structure 160 located between the ovonic threshold switching material portion 152 and one of the first or the second electrically conductive lines (e.g., the second electrically conductive line 90).

In one embodiment, a method of operating the ovonic memory element 150 includes programming the ovonic threshold switching material portion 152 to store data by applying a programming voltage between the first electrode 151 and the second electrode 153; and reading the data stored in the ovonic threshold switching material portion 152 by applying a read voltage between the first electrode 151 and the second electrode 153, wherein the ovonic memory element 150 has a ΔVth/Vth value of greater than 15%.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. An ovonic memory element, comprising:
a first electrode;
a second electrode; and
an ovonic threshold switching material portion located between the first electrode and the second electrode, wherein a first surface of the ovonic threshold switching material portion facing the first electrode is wider than an opposing second surface of the ovonic threshold switching material portion facing the second electrode.

2. The ovonic memory element of claim 1, wherein:
the first surface of the ovonic threshold switching material portion contacts the first electrode; and
the second surface of the ovonic threshold switching material portion contacts the second electrode.

3. The ovonic memory element of claim 2, wherein the first electrode is located above the second electrode.

4. The ovonic memory element of claim 2, wherein the first electrode is located below the second electrode.

5. The ovonic memory element of claim 1, wherein the ovonic threshold switching material portion comprises a chalcogenide material.

6. The ovonic memory element of claim 1, wherein the ovonic threshold switching material portion has a shape of a frustrum.

7. The ovonic memory element of claim 6, wherein a tapered surface of the ovonic threshold switching material portion continuously extends from the first electrode to the second electrode.

8. The ovonic memory element of claim 6, wherein the ovonic threshold switching material portion has a variable horizontal cross-sectional area that decreases with a vertical distance from the second electrode to the first electrode.

9. The ovonic memory element of claim 8, wherein the ovonic threshold switching material portion has a circular or oval-shaped horizontal cross-sectional shape.

10. The ovonic memory element of claim 8, wherein the ovonic threshold switching material portion has a rectangular horizontal cross-sectional shape.

11. The ovonic memory element of claim 1, wherein the ovonic threshold switching material portion is configured to store data.

12. The ovonic memory element of claim 1, wherein the ovonic memory element has a ΔVth/Vth value of greater than 15%.

13. A memory device, comprising
the ovonic memory element of claim 1;
a first electrically conductive line that laterally extends along a first horizontal direction and electrically connected to the first electrode;
a second electrically conductive line that laterally extends along a second horizontal direction and electrically connected to the second electrode; and
a metallic pillar structure located between the ovonic threshold switching material portion and one of the first or the second electrically conductive lines.

14. A method of operating the ovonic memory element of claim 1, comprising:
programming the ovonic threshold switching material portion to store data by applying a programming voltage between the first electrode and the second electrode; and
reading the data stored in the ovonic threshold switching material portion by applying a read voltage between the first electrode and the second electrode, wherein the ovonic memory element has a ΔVth/Vth value of greater than 15%.

15. A method of forming a memory device, comprising:
forming first electrically conductive lines laterally extending along a first horizontal direction;
forming an ovonic threshold switching material layer over the first electrically conductive lines;
patterning the ovonic threshold switching material layer into a two-dimensional array of ovonic threshold switching material portions having a respective shape of a frustum; and
forming second electrically conductive lines laterally extending along a second horizontal direction over the two-dimensional array of ovonic threshold switching material portions.

16. The method of claim 15, further comprising:
forming a metallic hard mask layer over the ovonic threshold switching material layer;
patterning the metallic hard mask layer into a two-dimensional array of metallic pillar structures, wherein the ovonic threshold switching material layer is patterned by transferring a pattern in the two-dimensional array of metallic pillar structures through the ovonic threshold switching material layer.

17. The method of claim 15, wherein patterning the ovonic threshold switching material layer comprises performing a reactive ion etching process with an undercut.

18. The method of claim 15, wherein patterning the ovonic threshold switching material layer comprises performing an ion beam etching process.

19. The method of claim 18, wherein:
the ion beam etching process comprises a two step ion beam etching process comprising a lower angle first step ion beam etching process and a higher angle second ion beam etching process; and
the ovonic threshold switching material portions have a variable horizontal cross-sectional area that increases with a vertical distance from the first electrically conductive lines.

20. The method of claim 18, wherein:
the ion beam etching process comprises a one-step ion beam etching process; and
the ovonic threshold switching material portions have a variable horizontal cross-sectional area that decreases with a vertical distance from the first electrically conductive lines.
